(19) United States
(12) Patent Application Publication
(10) Pub. No.: US 2024/0172512 A1
(43) Pub. Date: May 23, 2024

(54) LIGHT EMITTING DISPLAY DEVICE

(71) Applicant: Samsung Display Co., Ltd.

(72) Inventors: Dong Hee SHIN, Yongin-si (KR); Sun Kwun SON, Yongin-si (KR)

(21) Appl. No.: 18/211,290

(22) Filed: Jun. 19, 2023

(30) Foreign Application Priority Data
Nov. 23, 2022 (KR) 10-2022-0158463

(51) Int. Cl. H10K 59/35; H10K 59/121; H10K 59/122; H10K 59/131

(52) U.S. Cl. CPC H10K 59/353; H10K 59/1213; H10K 59/1216; H10K 59/122; H10K 59/131

(57) ABSTRACT

A light emitting display device is disclosed that includes a substrate, a first unit pixel, and a second unit pixel. The first unit pixel is disposed on the substrate and includes a first light emitting region, a second light emitting region, and a third light emitting region configured to emit first color light, second color light, and third color light, respectively. The second unit pixel is disposed on the substrate, arranged adjacent to the first unit pixel, and includes the first light emitting region, the second light emitting region, and the third light emitting region configured to emit the first color light, the second color light, and the third color light, respectively. The first, second, and third light emitting regions of the first unit pixel are sequentially arranged in a first diagonal direction. The first, second, and third light emitting regions of the second unit pixel are sequentially arranged in a second diagonal direction, which is different from the first diagonal direction. A laser drilling position opening is located on a center line between the first unit pixel and the second unit pixel, and does not overlap the first, second, and third light emitting regions of the first and second unit pixels.

### CROSS-REFERENCE TO RELATED APPLICATION

This application claims priority to and the benefit of Korean Patent Application No. 10-2022-0158463 filed in the Korean Intellectual Property Office on Nov. 23, 2022, the entire contents of which are incorporated herein by reference.

### BACKGROUND

### 1. Field

The present disclosure relates to a light emitting display device.

### 2. Description of the Related Art

Display devices includes liquid crystal displays, an organic light emitting diode (OLED) displays, and the like. Such display devices are used in various electronic devices such as portable phones, navigation devices, digital cameras, electronic books, portable game devices, or various terminals.

The OLED displays have self-luminance characteristics, and unlike liquid crystal displays, it does not require a separate light source, and accordingly thickness and weight can be reduced. In addition, the OLED display has high quality characteristics such as low power consumption, high luminance, and fast response speed.

### SUMMARY

Embodiments of the present disclosure may provide a light emitting display device that secures a space for of laser drilling for transmitting a voltage using a laser. Embodiments of the present disclosure may provide a light emitting display device in which color jamming does not occur.

Embodiments of the present disclosure may provide a high-resolution light emitting display device.

An embodiment of a light emitting display device includes a substrate including a surface defined by a first direction and a second direction and a thickness defined by a third direction, a first unit pixel disposed on the substrate and including a first light emitting region, a second light emitting region, and a third light emitting region configured to emit a first color light, a second color light, and a third color light, respectively, a second unit pixel disposed on the substrate and including the first light emitting region, the second light emitting region, and the third light emitting region configured to emit the first color light, the second color light, and the third color light, respectively, wherein the first unit pixel and the second unit pixel are adjacently arranged in the second direction, the first light emitting region, the second light emitting region, and the third light emitting region of the first unit pixel are sequentially arranged in a first diagonal direction with respect to the first and second directions, the first light emitting region, the second light emitting region, and the third light emitting region of the second unit pixel are sequentially arranged in a second diagonal direction with respect to the first and second directions, the first diagonal direction is different from the second diagonal direction, and a laser drilling position opening formed by laser drilling is located on a center line between the first unit pixel and the second unit pixel, and does not overlap the first, second, and third light emitting regions of the first unit pixel and the second unit pixel.

The first diagonal and second directions may be arranged in a chevron shape, the chevron shape may include a center point where the first and second diagonal directions meet, a first end located along the first diagonal distal from the center point, and a second end located along the second diagonal direction distal from the center point, the first light emitting regions of the first and second unit pixels may be disposed near the first end of the chevron shape and near the center point of the chevron shape, respectively, and the third light emitting regions may be disposed near the center point of the chevron shape and near the second end of the chevron shape, respectively.

The third light emitting region of the first unit pixel and the first light emitting region of the second unit pixel may be disposed near the center point of the chevron shape.

The light emitting display device further includes a third unit pixel and a fourth unit pixel, wherein the first unit pixel, the second unit pixel, the third unit pixel, and the fourth unit pixel are arranged in a 2×2 matrix format, each of the third and fourth unit pixels include the first, second, and third light emitting regions, the first light emitting region, the second light emitting region, and the third light emitting region of the third unit pixel are sequentially arranged in a third diagonal direction, and the first light emitting region, the second light emitting region, and the third light emitting region of the fourth unit pixel are sequentially arranged in a fourth diagonal direction.

The first diagonal direction and the third diagonal direction may be a same direction, and the second diagonal direction and the fourth diagonal direction may be the same direction.

The first diagonal direction and the fourth diagonal direction may be parallel but in opposite directions, and the second diagonal direction and the third diagonal direction may be parallel but in opposite directions.

Each of the first light emitting region, the second light emitting region, and the third light emitting region may have a planar polygonal shape.

the planar polygonal shape of each of the first light emitting region, the second light emitting region, and the third light emitting region may have at least one chamfered edge.

The light emitting display device may further include: a substrate; a semiconductor layer that is disposed on the substrate; a gate electrode that is disposed on the semiconductor layer; an interlayer insulating layer that covers the gate electrode; an anode that is disposed on the interlayer insulating layer; a pixel definition layer that includes an first opening overlapping the anode; an emission layer that is disposed on the anode; and a cathode that is disposed on the pixel definition layer and the emission layer, wherein each of the first light emitting region, the second light emitting region, and the third light emitting region may include the first opening of the pixel definition layer.

Each of the first, second, and third light emitting regions may include a light emitting element that comprises the anode, the emission layer, and the cathode.

The anode may be connected to the semiconductor layer through a second opening disposed in the interlayer insulating layer.

A connecting electrode may be disposed on the interlayer insulating layer at the laser drilling position opening formed by the laser drilling.

The connecting electrode may be disposed in the laser drilling position opening, and the connecting electrode may be connected to the cathode in the laser drilling position opening.

The connecting electrode may be disposed on a same layer as the anode. the connecting electrode may extend to an auxiliary low voltage line, and a material of the connecting electrode may be a same material as the anode.

The light emitting display device may further include a driving low voltage line disposed on the substrate; and an auxiliary driving low voltage line disposed on the substrate. The driving low voltage line and the auxiliary low voltage line may be disposed on different layers, the driving low voltage line and the auxiliary low voltage line may extend in different directions, the driving low voltage line and the auxiliary driving low voltage line may be configured to transmit a driving low voltage to the cathode.

The connecting electrode may connected the cathode to the auxiliary driving low voltage line.

The first unit pixel may include a first pixel, a second pixel, and a third pixel which may include the first, second, and third light emitting regions that emit the first, second, and third color light, respectively, the first pixel may include a first pixel driver and a first light emitting element, the second pixel may include a second pixel driver and a second light emitting, and the third pixel may include a third pixel driver and a third light emitting element.

Each of the first pixel driver, the second pixel driver, and the third pixel driving driver each may include a driving transistor and a storage capacitor, the storage capacitor may be connected to a gate electrode of the driving transistor, an electrode of the driving transistor included in the first pixel driver may be connected to an anode of the first light emitting element, an electrode of the driving transistor included in the second pixel driver may be connected to an anode of the second light emitting element, and an electrode of the driving transistor included in the third pixel driver may be connected to an anode of the third light emitting element.

Each of the first pixel driver, the second pixel driver, and the third pixel driver may further include an input transistor, and the input transistor may transmit a data voltage from a data line to the gate electrode of the driving transistor.

Each of the first pixel driver, the second pixel driver, and the third pixel driver may further include an initialization transistor, a voltage of each of the anode of the first light emitting element, the anode of the second light emitting element, and the anode of the third light emitting element may be sensed or initialized by the initialization transistor.

According to the embodiment, it is possible to secure a space where laser drilling can be carried even in a light emitting display device having a high number of pixels per inch by arranging light emitting regions or light emitting elements in adjacent two unit pixels in a bent shape.

According to the embodiment, it is possible to prevent a color jamming phenomenon from occurring by changing dispositions of colors in a plurality of unit pixels.

According to the embodiment, it is possible to provide a high-resolution light emitting display device by preventing a light emitting region or light emitting element of the same color from adjacent two unit pixels from being disposed such that the user does not see low resolution.

### BRIEF DESCRIPTION OF THE DRAWINGS

FIG. 1 is a schematic top plan view of a display area of a light emitting display device according to an embodiment.

FIG. 2 is a top plan view of positions of light emitting elements and a laser driving position in the light emitting display device according to the embodiment of FIG. 1.

FIG. 3 is a cross-sectional view of a light emitting display device according to the embodiment of FIG. 1.

FIG. 4 shows a light emitting element and a laser drilling position in a comparative example.

FIG. 5 is a circuit diagram of a pixel of the light emitting display device according to an embodiment.

FIG. 6 is a top plan view illustrating a light emitting element and a laser drilling position according to another embodiment.

FIG. 7 is a table that compares display characteristics according to embodiment and the comparative example.

FIGS. 8, 9, and 10 are top plan views of a light emitting element and a laser drilling position according to another embodiment.

FIG. 11 is a top plan view of a light emitting element and a laser drilling position according to a comparative example.

### DETAILED DESCRIPTION

Hereinafter, with reference to accompanying drawings, various embodiments will be described in detail such that a person of an ordinary skill can easily practice them in the technical field to which the present invention belongs. The present invention may be embodied in many different forms and is not limited to the embodiments described herein.

In order to clearly explain the present invention, parts irrelevant to the description have been omitted, and the same reference numerals are used for the same or similar constituent elements throughout the specification.

In addition, since the size and thickness of each component shown in the drawing is arbitrarily shown for convenience of description, the present invention is not necessarily limited to the drawings. In the drawings, the thickness of layers, films, panels, regions, etc., are exaggerated for clarity. In addition, in the drawing, the thickness of some layers and regions is exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “on” a reference portion will be understood to mean disposed above or below the reference portion, and will not necessarily be understood to mean disposed “at an upper side” based on an opposite to gravity direction.

In addition, unless explicitly described to the contrary, the word “comprise”, and variations such as “comprises” or “comprising”, and the word “include” and variations such as “includes” and “including” will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, throughout the specification, the term “connected” not means that two or more constituent elements are directly connected, but means that two or more constituent elements are indirectly connected through other constituent elements, physically connected, and electrically connected, or means that they are integrally formed even though they are referred to as different names depending on position or function.

In addition, in the entire specification, when parts such as wiring, layers, films, regions, plates, and constituent elements are “extended in the first direction or second direction”, this does not mean only a straight line shape extending straight in the corresponding direction, but also mean a structure that is generally extended along the first or second direction, which includes a structure that is bent at one part, a zigzag structure, or a structure that extends while including a curved line structure.

In addition, an electronic device (for example, mobile phone, TV, monitor, laptop computer, etc.) including a display device and a display panel manufactured by a manufacturing method described in the specification is not excluded from the scope of rights of this specification.

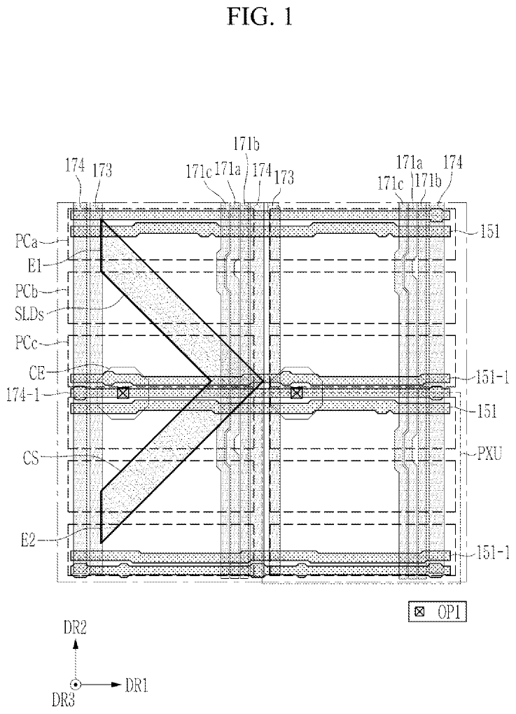

Hereinafter, a structure of a display area of a light emitting display device will be described in detail with reference to the drawings, and a schematic planar structure will be first described with reference to FIG. 1.

FIG. 1 is a schematic top plan view of a display area of a light emitting display device according to an embodiment.

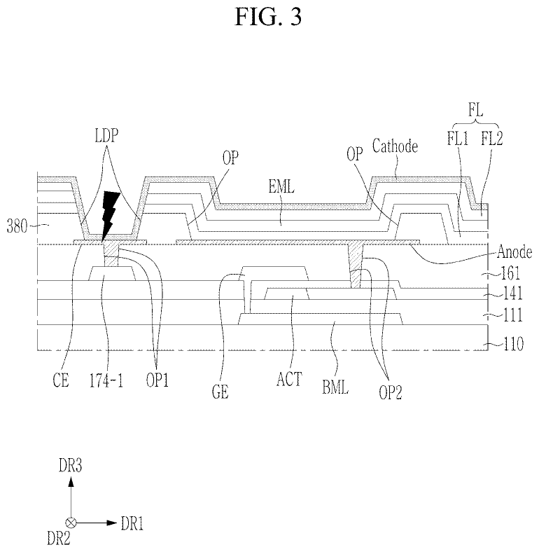

In FIG. 1, a part of the display area is illustrated in which a pixel includes a light-emitting element and a pixel driver. In FIG. 1, light emitting elements are not shown, and arrangement of the light emitting elements (hereinafter referred to as light emitting element disposition SLDs) of the light emitting element has a bent shape, and for example, it may have the chevron shape CS shown in FIG. 1. Here, a light emitting element may correspond to a light emitting region on a planar structure, and the light emitting region may correspond to an opening disposed on the pixel defining film 380 (refer to FIG. 3) or an emission layer EML disposed within the corresponding opening (refer to FIG. 3).

Hereinafter, a structure of a pixel driver in FIG. 1 will be described.

In FIG. 1, three pixel drivers PCa, PCb, and PCc adjacent to each other and defined with dotted lines are schematically illustrated.

The three pixel drivers PCa, PCb, and PCc form a pixel driving portion of a unit pixel PXU, respectively, and FIG. 1 shows four unit pixels PXU.

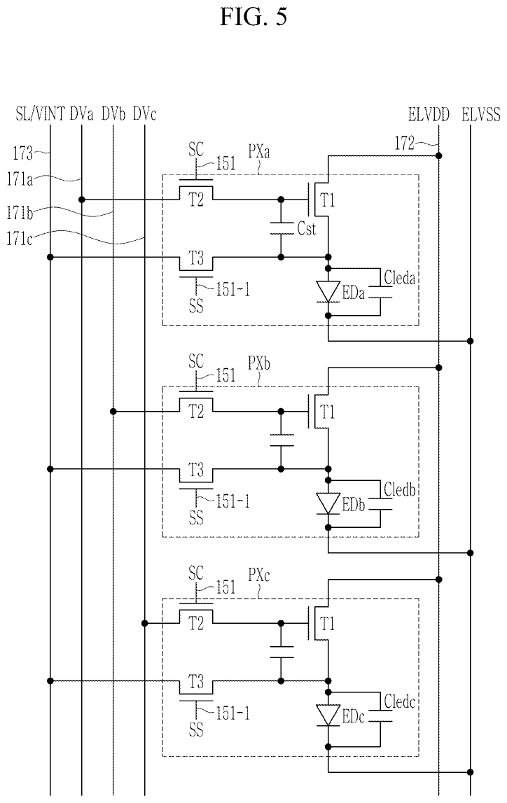

One unit pixel PXU may include three pixels corresponding to three primary colors (e.g., red, green, and blue). Three pixel drivers PCa, PCb, and PCc belonging to one unit pixel PXU may each have a structure that extends long in a first direction DR1, and the three pixel drivers PCa, PCb, and PCc correspond to the three pixels displaying three primary colors, respectively. Structures of the pixel drivers PCa, PCb, and PCc may vary, and according to an embodiment, and they may have the same circuit structure as in FIG. 5.

FIG. 1 additionally shows some wiring connected to pixel drivers PCa, PCb, and PCc. In FIG. 1, a first scan signal line 151 and a second scan signal line 151-1 extend in the first direction DR1, and data lines 171a, 171b, and 171c, a driving voltage line 172, an initialization voltage line 173, and a driving low voltage line 174 (hereinafter referred to as a second driving voltage line) extended to the second direction DR2 are also illustrated.

Here, the pixel drivers PCa, PCb, and PCc may be commonly connected to the first scan signal line 151, the second scan signal line 151-1, the driving voltage line (referring to 172 of FIG. 5), the initialization voltage line 173, and the driving low voltage line 174. In addition, the first pixel driver PCa may be connected to the first data line 171a, the second pixel driver PCb may be connected to the second data line 171b, and the third pixel driver PCc may be connected to the third data line 171c.

Each of the pixel drivers PCa, PCb, and PCc may correspond to one of thirds of the planar region partitioned by the first scan signal line 151, the second scan signal line 151-1, and the driving low voltage line 174.

Meanwhile, FIG. 1 also shows an auxiliary driving low voltage line 174-1 (hereinafter referred to as an auxiliary second driving voltage line) extended in the first direction DR1. The auxiliary driving low voltage line 174-1 is disposed on a different layer from the driving low voltage line 174 and extends in a different direction. Specifically, the auxiliary driving low voltage line 174-1 extending in the first direction is connected to the driving low voltage line 174 extending in the second direction DR2, and a driving low voltage ELVSS may be transmitted to the first direction DR1 and the second direction DR2 such that the driving low voltage ELVSS of a constant level may be applied over the entire display area of the light emitting display device. The driving low voltage ELVSS is applied to a cathode Cathode of the light emitting element. Referring to FIG. 3, the cathode Cathode is disposed above a pixel definition film (refer to 380 in FIG. 3), and is the uppermost side in the third direction DR3.

In order to electrically connect the uppermost cathode Cathode and the auxiliary driving low voltage line 174-1, a laser drilling method is used in the present embodiment. The laser drilling method is a method in which the cathode Cathode is electrically connected to the auxiliary driving low voltage line 174-1 disposed at the bottom by irradiating a laser while the cathode Cathode is formed to melt the irradiated part. In the embodiment of FIG. 1, a structure in which a connecting electrode CE is formed between the auxiliary driving low voltage line 174-1 and the cathode Cathode on the cross-section to mediate the electrical connection between the auxiliary driving low voltage line 174-1 and the cathode Cathode is illustrated. More specifically, in the embodiment of FIG. 1, the connecting electrode CE is electrically connected to the auxiliary driving low voltage line 174-1 through an opening OP1. The connecting electrode CE is electrically connected to the cathode Cathode through laser drilling. As a result, the cathode Cathode may receive the driving low voltage ELVSS through the auxiliary driving low voltage line 174-1. In such an embodiment, the connecting electrode CE may correspond to a position where laser drilling occurs on a plane. In addition, although they overlap with the connecting electrode CE on a plane, the first scan signal line 151 and the second scan signal line 151-1 disposed at the bottom are blocked by the connecting electrode CE during laser drilling, thereby preventing the first scan signal line 151 and the second scan signal line 151-1 from being short-circuited with the connecting electrode CE, and preventing transmission of the driving low voltage ELVSS. Therefore, when the connecting electrode CE is used, wiring can be formed on the lower side of the region where laser drilling is performed, and thus wiring and elements can be formed in a narrow area, improving the degree of integration.

A light emitting element (or light emitting region) may be disposed on top of the third direction DR3 of the pixel drivers PCa, PCb, and PCc. Referring to FIG. 1, it is illustrated that a plurality of light emitting elements (or light emitting regions) included in two adjacent unit pixels PXU in the second direction DR2 may be disposed in a chevron shape CS like light emitting element dispositions SLDs (also called arrangement of light emitting regions). The chevron shape CS may include a center point CP, a first end E1, and a second end E2. In addition, the light emitting element dispositions SLDs may have a structure bent in one direction in addition to the chevron shape, and in the embodiment of FIG. 1, it may have a structure bent in a direction by 90 degrees with respect to one diagonal direction. Depending on embodiments, the angle of bending may vary, the number of bends may be multiple, and the reference direction may also vary. That is, in the embodiment of FIG. 1, it is shown that the interval of the second direction DR2 widens as the light emitting element (or light emitting region) according to light emitting element dispositions SLD go in the reverse direction of the first direction DR1, but it can also be changed to an embodiment in which the interval of the first direction DR1 is widened toward a different direction, for example, the second direction DR2.

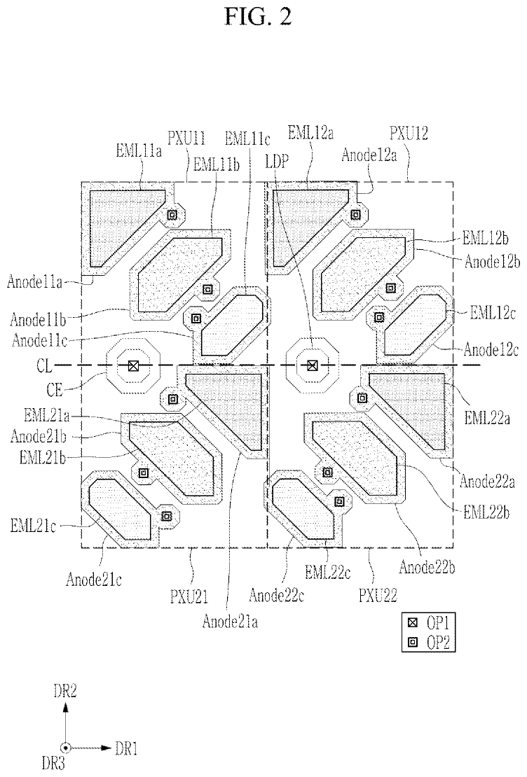

How the light emitting element disposition SLDs shown in FIG. 1 can be specifically disposed in an embodiment will be described with reference to FIG. 2.

FIG. 2 is a top plan view of positions of light emitting elements and a laser driving position in the light emitting display device according to the embodiment of FIG. 1.

In FIG. 2, the planar positions of first, second, third, and fourth unit pixels PXU11, PXU21, PXU12, and PXU22 are schematically illustrated by dotted lines.

Three light emitting elements are positioned on top of first, second, and third pixel drivers PCa, PCb, and PCc included in each of the first, second, third, and fourth unit pixels PXU11, PXU21, PXU12, and PXU22.

Referring to FIG. 1 and FIG. 2, the first pixel driver PCa is connected to each first anode Anode11a, Anode12a, Anode21a, and Anode32a through an opening OP2, the second pixel driver PCb is connected to each second anode Anode11b, Anode12b, Anode21b, and Anode32b through the opening OP2, and the third pixel driver PCc is connected to each third anode Anode11c, Anode12c, Anode21c, and Anode32c through the opening OP2. Referring to FIG. 2, each of the anodes Anode11a, Anode12a, Anode21a, Anode32a, Anode11b, Anode12b, Anode21b, Anode32b, Anode11c, Anode12c, Anode21c, and Anode32c may have a protruding portion, and the protruding portion may be connected with the respective pixel drivers PCa, PCb, and through the opening OP2.

In the embodiments of FIG. 1 and FIG. 2, a first light emitting element of the first, second, third, and fourth unit pixels PXU11, PXU21, PXU12, and PXU22 may include first anodes Anode11a, Anode12a, Anode21a, and Anode32a, first emission layers EML11a, EML12a, EML21a, and EML22a, respectively, and a cathode Cathode. The second light emitting element of the first, second, third, and fourth unit pixels PXU11, PXU21, PXU12, and PXU22 may include second anodes Anode11b, Anode12b, Anode21b, and Anode32b, second emission layers EML11b, EML12b, EML21b, and EML22b, respectively, and a cathode Cathode. The third light emitting element of the first, second, third, and fourth unit pixels PXU11, PXU21, PXU12, and PXU22 may include third anodes Anode11c, Anode12c, Anode21c, and Anode32c, third emission layers EML11c, EML12c, EML21c, and EML22c, respectively, and a cathode Cathode. In FIG. 2, the cathode Cathode may be positioned throughout the entire region.

In FIG. 2, the light emitting region corresponding to each light emitting element refers to a region where the emission layer included in each light emitting element is positioned or a region corresponding to the opening of the pixel definition film (refer to 380 in FIG. 3). In addition, the shape of each of the emission layers EML11a, EML12a, EML21a, EML22a, EML11b, EML12b, EML21b, EML22b, EML11c, EML12c, EML21c, and EML22c shown in FIG. 2 may correspond to the shape of the opening of the pixel definition film (refer to 380 in FIG. 3) and may correspond to the light emitting region.

In an embodiment, the first pixel unit PXU11 includes the first emission layer EML11a (which may be referred to as a first light emitting region), the second emission layer EML11b (which may be referred to as a second light emitting region), and the third emission layer EML11c (which may be referred to as a third light emitting region.

In an embodiment, the second pixel unit PXU21 includes the first emission layer EML21a (which may be referred to as the first light emitting region), the second emission layer EML21b (which may be referred to as the second light emitting region), and the third emission layer EML21c (which may be referred to as the third light emitting region.

In an embodiment, the third pixel unit PXU12 includes the first emission layer EML12a (which may be referred to as the first light emitting region), the second emission layer EML12b (which may be referred to as the second light emitting region), and the third emission layer EML12c (which may be referred to as the third light emitting region.

In an embodiment, the fourth pixel unit PXU22 includes the first emission layer EML22a (which may be referred to as the first light emitting region), the second emission layer EML22b (which may be referred to as the second light emitting region), and the third emission layer EML22c (which may be referred to as the third light emitting region.

In an embodiment, the first, second, and third light emitting regions emit a first color light, a second color light, and a third color light, respectively. The first color light may be red. The second color light may be green. The third color light may be blue.

The planar shape of each emission layer (or the opening of the pixel definition film (refer to 380 in FIG. 3)) may have a polygonal shape such as a triangle, and depending on embodiments, the polygon corner may have a chamfered structure. A planar shape of each emission layer (or the opening of the pixel definition film (refer to 380 in FIG. 3)) according to the embodiment of FIG. 2 will now be described.

The planar shape of the opening of the pixel definition film (refer to 380 in FIG. 3) corresponding to the first emission layer (EML11a, EML12a, EML21a, EML22a) or first emission layer (EML11a, EML12a, EML21a, EML22a) may be a triangle having at least one chamfered corner, and in the embodiment of FIG. 2, it may have a shape of a chamfered pentagon.

The planar shape of the opening of the pixel definition film (refer to 380 in FIG. 3) corresponding to the second emission layer (EML11b, EML12b, EML21b, EML22b) or the second emission layer (EML11b, EML12b, EML21b, EML22b) may be a hexagon, but depending on embodiments, it may have a structure of having at least one chamfered corner.

The planar shape of the opening of the pixel definition film (refer to 380 in FIG. 3) corresponding to the third emission layer (EML11c, EML12c, EML21c, EML22c) or the third emission layer (EML11c, EML12c, EML21c, EML22c) may be a hexagon having at least one chamfered corner, and in the embodiment of FIG. 2, it may have a chamfered heptagon.

The planar shape of each emission layer (or the opening of the pixel definition film (refer to 380 in FIG. 3)) shown in FIG. 2 may be changed in various ways depending on embodiments. In addition, the arrangement of each emission layer (or the opening of the pixel definition film (refer to 380 in FIG. 3)) may also be changed in various ways.

In the embodiment of FIG. 2, in the first unit pixel PXU11, the first, second and third emission layers E11a, E11b, and E11c or first, second, and third light emitting regions corresponding to each color are sequentially arranged in a first diagonal direction, and the first, second, and third emission layers E21a, E21b, and E21c, disposed in the second unit pixel PXU21 adjacent to the first unit pixel PX11 along the second direction DR2 are arranged in a second diagonal direction different from the first diagonal direction. The first and second diagonal directions are diagonal with respect to the first and second directions DR1 and DR2. Here, the colors of the emission layers or light emitting regions disposed at the end of the diagonal direction of the two unit pixels PXU are the same, the colors of the emission layer or light emitting regions disposed at the front ends of the diagonal direction of the two unit pixels PXUs are also the same, and the colors of the emission layer or emitting regions disposed in the middles of the diagonal direction of the unit pixel PXU may also be the same. Here, two emission layers or emitting regions included in different unit pixels and adjacent to each other can display different colors. In the embodiment of FIG. 2, the diagonal directions of the first unit pixel PXU11 and the third unit pixel PXU12 are the same, and the diagonal directions of the second unit pixel PXU21 and the fourth unit pixel PXU22 are the same.

The emission layer (or the opening of the pixel defining film (refer to 380 in FIG. 3)) having a planar shape as described above may be disposed in a chevron shape CS like the light emitting element disposition SLDs shown in FIG. 1.

Disposition of the emission layer (or the opening of the pixel definition film (refer to 380 in FIG. 3)) centered on the first and second unit pixels PXU11 and PXU21 positioned adjacently in the second direction DR2 in FIG. 2 will now be described.

First, the first, second, and third emission layers EML11a, EML11b, and EML11c of the first unit pixel PXU11 are arranged in a first diagonal direction, which is a direction between the first direction DR1 and the reverse of the second direction DR2. In addition, in the region of the first unit pixel PXU11 in FIG. 2, the first emission layer EML11a is disposed on the upper left, the second emission layer EML11b is disposed in the middle, and the third emission layer EML11c is disposed on the lower right.

On the other hand, the first, second, and third emission layers EML21a, EML21b, and EML21c of the second unit pixel PXU21 are arranged in a second diagonal direction between the reverse of the first direction DR1 and the reverse of the second direction DR2. In addition, in the region of the second unit pixel PXU21 of FIG. 2, the first emission layer EML21a is disposed on the upper right, the second emission layer EML21b is disposed in the middle, and the third emission layer EML21c is disposed on the lower left.

Each of the emission layers EML11a, EML11b, EML11c, EML21a, EML21b, and EML21c of the first and second unit pixels PXU11 and PXU21 may be disposed in the chevron shape CS shown as the light emitting element disposition SLDs of FIG. 1.

Meanwhile, the disposition of the emission layers EML11a, EML11b, EML11c, EML21a, EML21b, and EML21c of the first and second unit pixels PXU11 and PXU21 may have a symmetrical structure with respect to the center line CL. Here, the center line CL may have a direction parallel to the first direction DR1. In addition, the center line CL may be a line dividing between the first and second unit pixels PXU11 and PXU21.

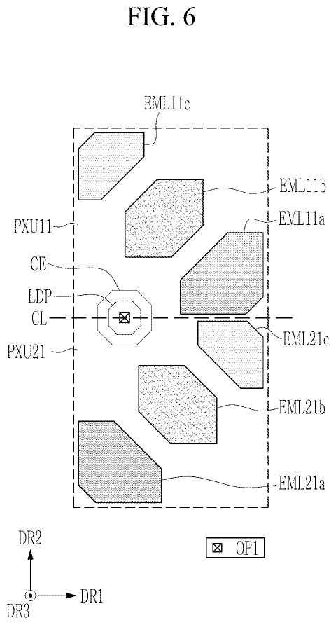

The disposition of each emission layer (or the opening of the pixel definition film (refer to 380 in FIG. 3)) may vary depending on embodiments, and numerous variations of the embodiment will be described in detail with reference to FIG. 6 and FIG. 8 to FIG. 10.

Meanwhile, a laser drilling position opening LDP through the pixel definition layer where laser drilling is performed as part of a manufacturing process is also shown in FIG. 2, and the connecting electrode CE disposed at the bottom of the laser drilling position opening LDP and in the opening OP1 such that the connecting electrode CE can be electrically connected to the auxiliary driving low voltage line 174-1 disposed at the bottom are also shown.

The laser drilling provides the laser drilling position opening in which connects the connecting electrode CE to the cathode Cathode by irradiating a laser to melt the insulating layers disposed between the connecting electrode CE and the cathode Cathode or by a laser irradiating the pixel definition layer 380 (FIG. 3) to ablate the pixel definition later 380. In this case, when a part melted by the laser may be large and when the laser is irradiated to the anode or other conductor, a short circuit may occur, thereby causing pixel malfunction. Therefore, it is necessary to allocate a certain area for laser drilling, and in the embodiment of FIG. 2, the connecting electrode CE and laser drilling position LDP are formed at a position that overlaps the center line CL of the disposition of the plurality of emission layers (or the opening of the pixel definition film (refer to 380 in FIG. 3)), thereby preventing occurrence of an improper short circuit. Therefore, the connecting electrode CE and the laser drilling position LDP overlap the center line CL crossing a boundary of two adjacent unit pixels in the second direction DR2. In addition, the laser drilling position LDP is formed at a position that does not overlap with each emission layer, anode, and/or light emitting region to prevent damage to the light emitting element during laser drilling.

A cross-section structure of the light emitting display device having the above flat shape will be described with reference to FIG. 3.

FIG. 3 is a cross-sectional view of a light emitting display device according to the embodiment of FIG. 1.

In the cross-section of FIG. 3, a cathode Cathode, a pixel definition film 380, an intermediate layer including a functional layer FL and an emission layer EML, and a layer corresponding to an anode Anode (which may be referred to as light emitting element layers), and an interlayer insulating layer 161 disposed below the light emitting element layer, and a conductive layer, a semiconductor layer, and an gate insulating layer 141 disposed below the interlayer insulating planarization layer 161 (which may be referred to as driving element layers). A light emitting element may be disposed on the light emitting element layer.

In FIG. 3, one of a first light emitting element, a second light emitting element, and a third light emitting element is illustrated, a path through which a current is transmitted from one transistor of pixel drivers PCa, PCb, and PCc to the anode Anode is illustrated along with an opening OP disposed on the pixel definition film 380. In addition, FIG. 3 schematically shows a laser drilling position opening LDP where laser drilling is performed as part of the manufacturing process of the display device.

FIG. 3 illustrates a structure of a lower portion of the anodes Anode1 and Anode2, that is, a structure of a driving element layer is briefly shown, and thus only one transistor is illustrated. A brief overview of the driving element layer structure from a substrate 110 to an interlayer insulating layer 161 is as follows.

The substrate 110 may include a material that has a rigid characteristic such as glass and does not bend, or may include a flexible material that can bend, such as plastic or polyimide. In the case of a flexible substrate, a double-layered structure of polyimide and a barrier layer formed of an inorganic insulating material thereon may be repeatedly formed.

A lower shielding layer BML containing a metal is disposed on the substrate 110, and the lower shielding layer BML may overlap on a plane with one channel of transistors positioned on pixel drivers PCa, PCb, and PCc included in the pixel. Depending on embodiments, a driving low voltage line 174 (FIG. 1) to which the driving low voltage ELVSS is applied may be disposed on the same layer as the lower shielding layer BML.

The substrate 110 and the lower shielding layer BML are covered by a buffer layer 111. The buffer layer 111 serves to block permeation of an impurity element in a semiconductor layer ACT, and may be an inorganic insulating layer including a silicon oxide (SiOₓ), a silicon nitride (SiNₓ), a silicon oxynitride (SiOₓN_{y}), and the like.

The semiconductor layer ACT formed of a silicon semiconductor (for example, polycrystalline semiconductor (P-Si)) or an oxide semiconductor is disposed on the buffer layer 111. The semiconductor layer ACT is a semiconductor layer disposed on pixel drivers PCa, PCb, and PCc included in the pixel, and may include a first region and a second region disposed on both sides of a channel of a transistor including a driving transistor. Here, the channel of the transistor may be a portion of the semiconductor layer ACT overlapping a gate electrode GE, and the first region and the second region may be portions of the semiconductor layer ACT that do not overlap the gate electrode GE. That is, the first region and the second region disposed on both sides of the channel of the semiconductor layer ACT are not covered by the gate electrode GE, and thus they have the characteristics of the conductive layer by plasma treatment or doping and may serve as a first electrode and a second electrode of the transistor.

A first gate insulating layer 141 may be disposed on the semiconductor layer ACT. The first gate insulating layer 141 may be an inorganic insulating layer including a silicon oxide (SiOₓ), a silicon nitride (SiNₓ), a silicon oxynitride (SiOₓN_{y}), or the like.

A first gate conductive layer including a gate electrode GE of a transistor disposed on the pixel drivers PCa, PCb, and PCc may be disposed on the first gate insulating layer 141. The auxiliary driving low voltage line 174-1 is disposed on the first gate insulating layer 141, and a scan line may be formed in addition to the gate electrode GE of the transistor disposed on the pixel drivers PCa, PCb, and PCc. Meanwhile, the first gate conductive layer may include one electrode of one capacitor disposed on the pixel drivers PCa, PCb, and PCc. The first gate conductive layer may include a metal such as aluminum (Al), copper (Cu), molybdenum (Mo), titanium (Ti), and the like or a metal alloy thereof, and may be formed of a single layer or multiple layers.

After forming the first gate conductive layer, an exposed region of the first semiconductor layer can be made conductive by performing a plasma treatment or doping process. That is, the semiconductor layer ACT covered by the gate electrode GE does not become conductive, and a portion of the semiconductor layer ACT not covered by the gate electrode GE may have the same characteristics as the conductive layer.

The interlayer insulating layer 161 may be disposed on the first gate conductive layer and the first gate insulating layer 141. The first interlayer insulating layer 161 may include an inorganic insulating layer including a silicon oxide (SiOₓ), a silicon nitride (SiNₓ), a silicon oxynitride (SiOₓN_{y}), or the like, and depending on embodiments, it may be formed by a thick inorganic insulating material. In addition, depending on embodiments, the interlayer insulating layer 161 may be formed of an organic insulator and may include at least one material selected from a group consisting of polyimide, polyamide, acryl resin, benzocyclobutene, and phenol resin.

An anode layer including an anode Anode and a connecting electrode CE is disposed on the interlayer insulating layer 161. The anode Anode is connected to a second region of the semiconductor layer ACT serving as the second electrode of the transistor through a second opening OP2 disposed on the interlayer insulating layer 161 and the first gate insulating layer 141. As a result, the anode Anode may receive an output of the transistor. The connecting electrode CE is formed of the same material as the anode Anode, and extends to the auxiliary driving low voltage line 174-1 connecting the cathode Cathode to the auxiliary low voltage line 174-1 through a first opening OP1 disposed in the interlayer insulating layer 161. As a result, the connecting electrode CE receives the driving low voltage ELVSS. The anode layer may be formed of a single layer including a transparent conductive oxide film or a metal material or a multi-layer including these. The transparent conductive oxide layer may include an indium tin oxide (ITO), a poly-ITO, an indium zinc oxide (IZO), an indium gallium zinc oxide (IGZO), and an indium tin zinc oxide (ITZO). The metal material may include silver (Ag), molybdenum (Mo), copper (Cu), gold (Au), and aluminum (Al).

A pixel definition film 380 including an opening OP is formed on the anode layer.

An opening OP (hereinafter also referred to as light emitting element opening) of the pixel definition film 380 is a portion corresponding to the light emitting region and/or emission layer EML, and may exposes a portion of the anode Anode and have a tapered side wall.

The emission layer EML is disposed within the opening OP of the pixel definition film 380, and the emission layer EML may also be disposed on the pixel definition film 380.

A first functional layer FL1 may be disposed between the anode Anode and the emission layer EML, and a second functional layer FL2 may be positioned on the emission layer EML. Here, the first functional layer FL1 may include a hole injection layer and/or a hole transport layer, and the second functional layer FL2 may include an electron transport layer and/or an electron injection layer. Here, the functional layer FL and the emission layer EML together may be referred to as an intermediate layer. The first functional layer FL1 and the second functional layer FL2 are formed above the pixel definition film 380 and also within the opening OP. Therefore, in the embodiment of FIG. 3, both the intermediate layers are disposed above the pixel definition film 380 and within the opening OP. However, depending on embodiments, the emission layer EML is disposed only within the opening OP of the pixel definition film 380, and the functional layer FL may be formed on the pixel definition film 380 and also within the opening OP.

A cathode Cathode is formed above the second functional layer FL2 and also above the pixel definition film 380 and the opening OP.

The anode Anode, the emission layer EML, and the cathode Cathode form a light emitting element, and the light emitting element may further include the functional layer FL.

A current transmitted to the anode Anode passes through the first functional layer FL1, the emission layer EML, and the second functional layer FL2, and is then transmitted to the cathode Cathode. In this case, the emission layer EML emits light due to the current flowing through the emission layer EML, and the first light emitting element shows luminance.

Referring to FIG. 3, the cathode Cathode is connected to the connecting electrode CE at the laser drilling position opening LDP and receives the driving low voltage ELVSS from the auxiliary driving low voltage line 174-1 through the connecting electrode CE.

In FIG. 3, a cross-section structure of the laser drilling position opening LDP where laser drilling is performed is shown, and the cathode Cathode, the functional layer FL, the emission layer EML, and the pixel definition film 380 are connected with the connecting electrode CE there below while having neat openings. However, since the intermediate layer and the pixel definition film 380 are melted by the laser or the pixel definition film 380 is ablated by the laser drilling, and the cathode Cathode and the connecting electrode CE are electrically connected, it may have a cross-section structure that is not as neat as shown in FIG. 3.

Meanwhile, depending on embodiments, a spacer may be further formed on the pixel definition film 380, and the spacer may have a tapered side wall like the pixel definition film 380.

The structure on the cathode is not shown in FIG. 3, but an encapsulation layer may be disposed on the cathode Cathode depending on embodiments. The encapsulation layer may include at least one inorganic layer and at least one organic layer, and may have a three-layer structure including a first inorganic encapsulation layer, an organic encapsulation layer, and a second inorganic encapsulation layer. The encapsulation layer may be provided for protecting the emission layer EML from moisture or oxygen that may inflow from the outside. Depending on embodiments, the encapsulation layer may include a structure in which an inorganic layer and an organic layer are sequentially stacked.

Depending on embodiments, a sensing insulating layer and a plurality of sensing electrodes may be disposed on the encapsulation layer for touch sensing.

Depending on embodiments, a film including a polarizer may be attached to the encapsulation layer to reduce reflection of external light. In addition, a color filter or a color conversion layer may be further formed to improve color quality, and in this case, a polarizer may not be attached. A light blocking layer may be disposed between the color filters or the color conversion layer. In addition, depending on embodiments, a material that can absorb some wavelengths of external light (hereinafter, referred to as a reflection control material) may further include a layer formed thereon, and in this case, a polarizer may not be attached. In addition, depending on embodiments, a front surface of the light emitting display device may be flattened by covering it with an additional organic film (also referred to as a planarization film).

FIG. 3 shows a cross-sectional structure according to an embodiment, and therefore, numerous variations are applicable to the structure.

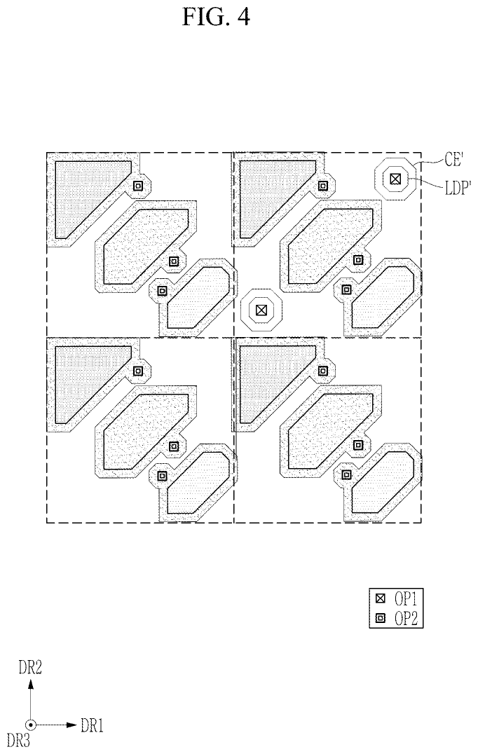

Hereinafter, a disposition structure of a light emitting region according to a comparative example that is different from the embodiment of FIG. 2 will be described with reference to FIG. 4.

FIG. 4 shows a light emitting element and a laser drilling position in a comparative example.

Not as in FIG. 2, in FIG. 4, all unit pixels have the same disposition of light emitting regions. That is, in FIG. 4, the same light emitting region disposition as the unit pixel PXU11 of FIG. 4 is formed repeatedly. As a result, in the comparative example of FIG. 4, there is less space to perform laser drilling compared to the embodiment of FIG. 2. Therefore, a connecting electrode CE′ according to the comparative example of FIG. 4 is smaller than the size of the connecting electrode CE according to embodiment of FIG. 2. As a result, in the comparative example of FIG. 4, the area of a laser drilling position LDP′ where laser drilling can be performed according to the comparative example of FIG. 4 is smaller than the area of the laser drilling position LDP where laser drilling can be performed according to the embodiment of FIG. 2.

As the light emitting display device has a higher resolution, the area of the pixel decreases, and as a space to perform laser drilling decreases, the drawback that actual laser drilling cannot be performed occurs. However, in the embodiment of FIG. 2, although the pixel area is reduced, it may have the merit of performing laser drilling by changing the disposition of the light emitting region.

Hereinafter, a pixel structure of a pixel included in the light emitting display device will be described with reference to FIG. 5.

FIG. 5 is a circuit diagram of a pixel of the light emitting display device according to an embodiment.

In FIG. 5, a circuit diagram of the three pixels PXa, PXb, and PXc is illustrated.

The plurality of pixels may include the first pixel PXa, the second pixel PXb, and the third pixel PXc. Each of the first pixel PXa, the second pixel PXb, and the third pixel PXc includes plurality of transistors T1, T2, and T3, a storage capacitor Cst, and light emitting elements EDa, EDb, and EDc. Here, the respective pixels PXa, PXb, and PXc may be distinguished by the light emitting elements EDa, EDb, and EDc and pixel drivers PCa, PCb, and PCc, and the pixel drivers PCa, PCb, and PCc may correspond to portions displayed by the dotted line in FIG. 1. Referring FIG. 5, the pixel drivers PCa, PCb, and PCc include a plurality of transistors T1, T2, and T3 and a storage capacitor Cst corresponding to a portion excluding the light emitting elements EDa, EDb, and EDc in each pixel PXa, PXb, and PXc.

In addition, depending on embodiments, capacitors Cleda, Cledb, and Cledc (hereinafter referred to as light emitting capacitors) connected to both ends of the light emitting elements EDA, EDb, and EDc may be further included, and the light emitting capacitors Cleda, Cledb, and Cledc may not be included in the pixel drivers and may be included in light emitting elements EDa, EDb, and EDc.

The plurality of transistors T1, T2, and T3 are formed by one driving transistor T1 (also referred to as a first transistor) and two switching transistors T2 and T3, and the two switching transistors are distinguished by an input transistor T2 (also referred to as a second transistor) and an initialization transistor T3 (also referred to as a third transistor). Each of the transistors T1, T2, and T3 includes a gate electrode, a first electrode, and a second electrode, respectively, and also includes a semiconductor layer including a channel such that a current flows or blocks the channel of the semiconductor layer according to a voltage of the gate electrode. Here, one of the first electrode and the second electrode may be a source electrode and the other may be a drain electrode according to the voltage applied to each of the transistors T1, T2, and T3.

The gate electrode of the driving transistor T1 is connected to one end of the storage capacitor Cst, and is also connected to the second electrode (output side electrode) of the input transistor T2. In addition, the first electrode of the driving transistor T1 is connected to a driving voltage line 172 that transmits a driving voltage ELVDD, and the second electrode of the driving transistor T1 is connected with anodes of the light emitting elements EDa, EDb, and EDc, the other end of the storage capacitor Cst, the first electrode of the initialization transistor T3, and one of ends of the light emitting capacitors Cleda, Cledb, and Cledc. The driving transistor T1 receives data voltages DVa, DVb, and DVc to the gate electrode according to the switching operation of the input transistor T2, and may supply a driving current to the light emitting elements EDa, EDb, and EDc according to the voltage of the gate electrode. In this case, the storage capacitor Cst stores and maintains the voltage of the gate electrode of the driving transistor T1.

The gate electrode of the input transistor T2 is connected to a first scan signal line 151 that transmits a first scan signal SC. The first electrode of input transistor T2 is connected to data lines 171a, 171b, and 171c that transmit data voltages DVa, DVb, and DVc, and the second electrode of the input transistor T2 is connected with one end of the storage capacitor Cst and the gate of the driving transistor T1. A plurality of data lines 171a, 171b, and 171c transmit different data voltages DVa, DVb, and DVc, respectively, and the input transistors T2 of the respective pixels PXa, PXb, and PXc are connected to different data lines 171a, 171b, and 171c. The gate electrode of the input transistor T2 of each of the pixels PXa, PXb, and PXc is connected to the same first scan signal line 151 and may receive the first scan signal SC of the same timing. Although the input transistor T2 of each of the pixels PXa, PXb, and PXc is turned on simultaneously by the first scan signal SC at the same timing, different data voltages DVa, DVb, and DVc are transmitted to the gate electrode of the driving transistor T1 and one end of the storage capacitor Cst of each pixel PXa, PXb, and PXc through different data lines 171a, 171b, and 171c.

In the embodiment of FIG. 5, the gate electrode of the initialization transistor T3 receives a different scan signal from the gate electrode of the input transistor T2.

The gate electrode of the initialization transistor T3 is connected to a second scan signal line 151-1 that transmits a second scan signal SS. The first electrode of the initialization transistor T3 is connected to the other end of the storage capacitor Cst, the second electrode of the driving transistor T1, the anodes of the light emitting elements EDa, EDb, and EDc, and one of ends of the light emitting capacitors Cleda, Cledb, and Cledc, and the second electrode of the initialization transistor T3 is connected to the initialization voltage line 173 that transmits an initialization voltage VINT. The initialization transistor T3 is turned on according to the second scan signal SS and transmits the initialization voltage VINT to the anodes of the light emitting elements EDa, EDb, and EDc, one of ends of the light emitting capacitors Cleda, Cledb, and Cledc, and the other end of the storage capacitor Cst to initialize the voltage of the anodes of the light emitting elements EDa, EDb, and EDc.

The initialization voltage line 173 may function as a sensing wire SL by performing an operation of sensing the voltages of the anodes of the light emitting elements EDa, EDb, and EDc before applying the initialization voltage VINT. Through the sensing operation, it can be determined whether the voltage of the first anode is maintained at a target voltage. The sensing operation and the initialization operation of transmitting the initialization voltage VINT may be separated in time and proceed, and the initialization operation may be performed after the sensing operation is performed.

In the embodiment of FIG. 5, the turn-on period of the initialization transistor T3 and the input transistor T2 can be distinguished, and thus a write operation performed by the input transistor T2 and the initialization operation (and/or detection operation) performed by the initialization transistor T3 can be performed at different timings.

One end of the storage capacitor Cst is connected to the gate electrode of the driving transistor T1 and the second electrode of the input transistor T2, the other end is connected to the first electrode of the initialization transistor T3, the second electrode of the driving transistor T1, the anodes of the light emitting elements EDa, EDb, and EDc, and one ends of the light emitting capacitors Cleda, Cledb, and Cledc.

The light emitting elements EDa, EDb, and EDc receive the output current of the driving transistor T1 through the anodes, and the cathodes of the light emitting elements EDa, EDb, and EDc receive the driving low voltage ELVSS through the driving low voltage line 174, and the light emitting elements EDa, EDb, and EDc emit light according to the output current of the driving transistor T1 to display gray scales.

In addition, the light emitting capacitors Cleda, Cledb, and Cledc are formed at both ends of the light emitting elements EDa, EDb, and EDc, and thus the voltage at both ends of the light emitting elements EDa, EDb, and EDc can be maintained constant such that the light emitting elements EDa, EDb, and EDc can display constant luminance.

Hereinafter, operation of a pixel having the circuit of FIG. 5 will be simply described.

In the embodiment shown in FIG. 5, the respective transistors T1, T2, and T3 are N-type transistors, and they have the characteristic of being turned on when a high-level voltage is applied to the gate electrode. However, depending on embodiments, each of the transistors T1, T2, and T3 may be a P-type transistor.

As an emission period ends, one frame begins. Then, a high-level second scan signal SS is supplied to turn on the initialization transistor T3. When the initialization transistor T3 is turned on, an initialization operation and/or a sensing operation may be performed.

Focusing on the embodiment in which both the initialization operation and the sensing operation are performed, it is as follows.

The sensing operation may be performed first before an initialization operation is performed. That is, as the initialization transistor T3 is turned on, the initialization voltage line 173 serves as a sensing wire SL to sense the voltage of the anode of each of the light emitting elements EDA, EDb, and EDc. Through the sensing operation, it is possible to determine whether the voltage of the anode is maintained at the target voltage.

After that, the initialization operation may be performed, and the voltage of the other end of the storage capacitor Cst, the second electrode of the driving transistor T1, and the anodes of the light emitting elements EDa, EDb, and EDc are changed to the initialization voltage VINT to thereby perform the initialization operation.

In this way, the sensing operation and the initialization operation that transmits the initialization voltage VINT are separated in time, and thus the pixel can perform various operations while using a minimum number of transistors and reducing the area occupied by the pixel. As a result, resolution of the display panel can be improved.

Along with the initialization operation or at separate timing, the first scan signal SC is also changed to a high level and applied, the input transistor T2 is turned on, and the write operation is performed. That is, the data voltages DVa, DVb, and DVc from the data lines 171a, 171b, and 171c are input to the gate electrode of the driving transistor T1 and one end of the storage capacitor Cst through the turned-on input transistor T2 and stored.

The data voltages DVa, DVb, and DVc and the initialization voltage VINT are applied to both ends of the storage capacitor Cst by the initialization operation and the write operation, respectively. When the initialization transistor T3 is turned on, although the output current is generated from the driving transistor T1, it can be output to the outside through the initialization transistor T3 and the initialization voltage line 173, and thus it may not be input to first anodes of the first light emitting elements EDa1, EDb1, and EDc1. In addition, depending on embodiments, during the writing period in which the high-level first scan signal SC is supplied, the driving voltage ELVDD is applied as a low-level voltage, or the driving low voltage ELVSS is applied as a high level voltage such that the current does not flow to the light emitting elements EDa, EDb, and EDc.

After that, when the first scan signal SC is changed to a low level, the driving transistor T1 generates and outputs a current by the high-level driving voltage ELVDD applied to the driving transistor T1 and the gate voltage of the driving transistor T1 stored in the storage capacitor Cst. The output current of the driving transistor T1 is input to the light emitting elements EDa, EDb, and EDc, and the light emitting period in which the light emitting elements EDa, EDb, and EDc emit light proceeds.

Hereinafter, an embodiment of having another planar shape of an emission layer (or an opening of a pixel definition film 380 (refer to FIG. 3)) different from FIG. 2 will be described with reference to FIG. 6.

FIG. 6 is a top plan view illustrating a light emitting element and a laser drilling position according to another embodiment.

In an embodiment of FIG. 6, emission layers (or pixel definition films 380 (refer to FIG. 3) are arranged similarly to that of the embodiment of FIG. 2, but they may be arranged different from FIG. 2 based on colors.

That is, emission layers EML11a, EML11b, and EML11c of a unit pixel PXU11 are arranged in a diagonal direction between the reverse direction of a first direction DR1 and a second direction DR2. Not as in the embodiment shown in FIG. 2, in a region of the unit pixel PXU11 of FIG. 6, the first emission layer EML11a is disposed on the lower right, the second emission layer EML11b is disposed in the middle, and the third emission layer EML11c is disposed on the upper left.

Meanwhile, the emission layers EML21a, EML21b, and EML21c of a unit pixel PXU21 are arranged in a diagonal direction between the reverse of the first direction DR1 and the reverse of the second direction DR2. Not as in the embodiment shown in FIG. 2, in a region of the unit pixel PXU11 of FIG. 6, the first emission layer EML21a is disposed on the lower left, the second emission layer EML21b is disposed in the middle, and the third emission layer EML21c is disposed on the upper right.

In the embodiment of FIG. 6, three emission layers or emitting regions corresponding to each color are sequentially arranged in a diagonal direction in one unit pixel PXU, and the three emission layers disposed in the adjacent unit pixel PXU along the second direction DR2 are arranged in a different direction from the diagonal direction in which they are arranged. Here, the emission layers or emitting regions positioned at the end of the diagonal directions of the two unit pixel PXUs have the same color, the emission layers or emitting regions positioned in the front of the diagonal directions of the two unit pixel PXUs may also have the same color, and the emission layers or emitting regions positioned in the middle of the diagonal directions of the two unit pixel PXUs may also have the same color. Here, two emission layers or emitting regions included in different unit pixels and adjacent to each other may display different colors.

A center of each of the emission layers EML11a, EML11b, EML11c, EML21a, EML21b, and EML21c of two unit pixels PXU11 and PXU21 may be disposed in the chevron shape shown as the light element dispositions SLDs of FIG. 1.

Meanwhile, the arrangement of emission layers EML11a, EML11b, EML11c, EML21a, EML21b, and EML21c of the two unit pixels PXU11 and PXU21 may have a symmetrical structure with respect to a center line CL. Here, the center line CL may have a direction parallel to the first direction DR1. In addition, the center line CL may be a line dividing between two unit pixels PXU11 and PXU21.

Meanwhile, a planar shape of each emission layer (or opening of the definition film 380 (refer to FIG. 3)) according to the embodiment of FIG. 6 is different from that of the embodiment of FIG. 2.

That is, in the embodiment of FIG. 6, the planar shape of all emission layers (or openings in the pixel definition film (refer to FIG. 3)) is hexagonal. However, depending on embodiments, at least one corner may have a chamfered structure.

The planar shape and disposition of each emission layer (or opening of the pixel definition film 380 (refer to FIG. 3)) shown in FIG. 6 may be changed in various ways depending on embodiments.

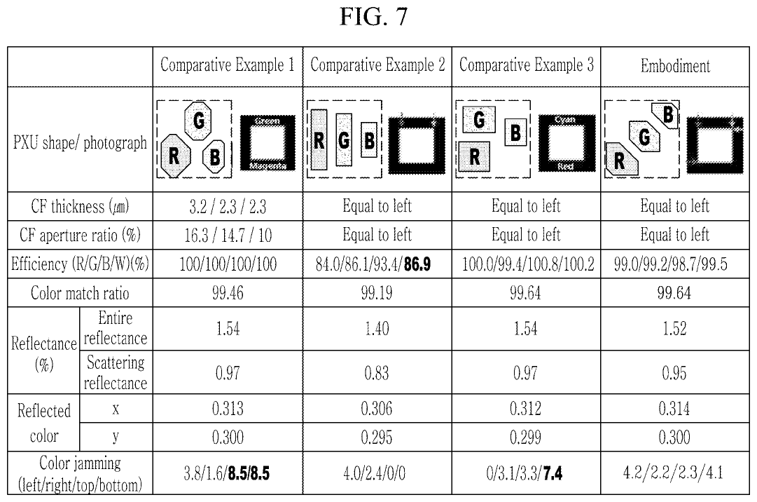

Hereinafter, referring to FIG. 7, display characteristics of the embodiment and the comparative example of FIG. 6 will be compared.

FIG. 7 is a table that compares display characteristics according to the embodiment and comparative examples.

In FIG. 7, together with the embodiment of FIG. 6, dispositions of light emitting regions in unit pixels PXU of three comparative examples are shown. The three comparative examples and the embodiment are formed identically except for the dispositions of the light emitting regions. That is, a thickness of the color filter CF formed on each of the light emitting display device is also formed the same, and the aperture ratios of red, green, and blue are also formed the same.

The three comparative examples and the embodiment are different in color efficiency, color matching rate, reflectance, and reflected color, but they are all within the usable range and do not show a big difference. Here, the color coordinate value described in FIG. 7 may be a value on the CIE1931 color space.

However, based on a color jamming phenomenon, the three comparative examples have drawbacks compared to the embodiment.

The color jamming phenomenon means that a specific color is visible at the boundary between black and white when white is displayed inside a black color background. The color jamming of FIG. 7 is expressed as a numerical value, and the higher the corresponding numerical value, the better the color is seen.

First, in Comparative Example 1, it can be confirmed that green and magenta colors can be seen well from the top and bottom, and in Comparative Example 3, red can be seen well from the bottom and cyan can be seen from the top. In contrast, in the embodiment, the colors of the left and bottom are similar to each other and color jamming that is displayed in the top and right are similar to each other, but values are not high in each direction and thus the color jamming is not visible to the user.

Meanwhile, in Comparative Example 2, it may have less color jamming than the embodiment, but in the case of formation as in Comparative Example 2, a space for laser drilling cannot be made and thus it is difficult to adopt when laser drilling is required. Therefore, in the present embodiment, laser drilling can be performed even through an area that a pixel may occupy is reduced at high resolution, and the color jamming phenomenon may be improved.

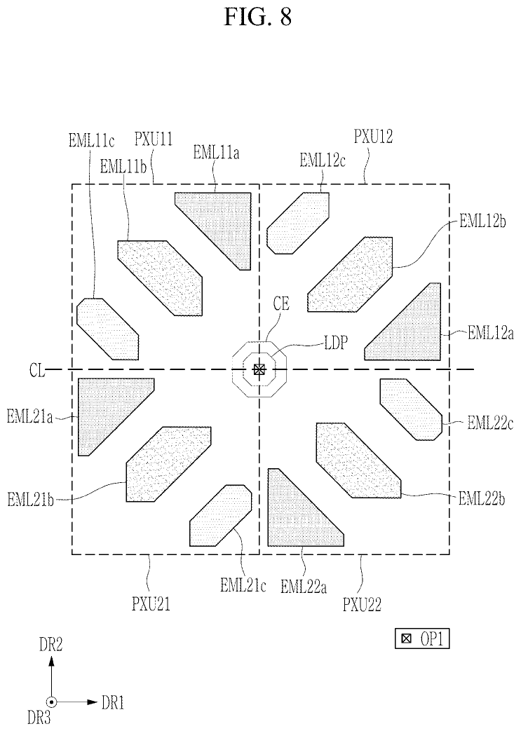

In the above, the arrangement of each emission layer (or the opening of the pixel definition film 380 (refer to FIG. 3)) in FIG. 2 and FIG. 6 has been described. However, depending on embodiments, arrangements other than the arrangement shown in FIG. 2 and FIG. 6 are also possible, and thus other embodiments will be described with reference to FIG. 8 to FIG. 10.

FIG. 8 to FIG. 10 are top plan views of a light emitting element and a laser drilling position according to another embodiment.

In the discussion of FIGS. 8 to 10, the discussion relative to FIG. 2 applies with the exceptions of the differences discussed below.

First, in an embodiment of FIG. 8, the planar shape of each emission layer (or opening of the pixel definition film 380 (refer to FIG. 3)) within unit pixels PXU adjacent to each other in a first direction DR1 has a symmetrical shape based on a line of a second direction DR2. In the embodiment as shown in FIG. 8, since light emitting element dispositions SLDs in the chevron shape CS shown in FIG. 1 face each other, dispositions of light emitting elements of four adjacent unit pixel PXUs may have a rhombus shape.

In the embodiment of FIG. 8, three emission layers or emitting regions corresponding to each color are sequentially arranged in a diagonal direction in one unit pixel PXU, and the three emission layers disposed in the adjacent unit pixels PXU along the second direction DR2 are arranged in a different direction from the diagonal direction in which they are arranged. Here, the emission layers or emitting regions positioned at the end of the diagonal directions of the two unit pixel PXUs have the same color, the emission layers or emitting regions positioned in the front of the diagonal directions of the two unit pixel PXUs may also have the same color, and the emission layers or emitting regions positioned in the middle of the diagonal directions of the two unit pixel PXUs may also have the same color. Here, two emission layers or emitting regions included in different unit pixels and adjacent to each other may display different colors. In the embodiment of FIG. 8, diagonal directions of a unit pixel PXU11 and a unit pixel PXU22 are parallel to each other but in opposite directions, and diagonal directions of a unit pixel PXU21 and a unit pixel PXU12 are also parallel to each other but in opposite directions.

Specifically, each of the emission layers EML11a, EML11b, and EML11c of the unit pixel PXU11 is arranged in a diagonal direction between the first direction DR1 and the second direction DR2. In addition, within a region of the unit pixel PXU11, the first emission layer EML11a is disposed on the upper right, the second emission layer EML11b is disposed in the middle, and the third emission layer EML11c is disposed on the lower left.

Emission layers EML12a, EML12b, and EML12c of a unit pixel PXU12 are arranged in a diagonal direction between the reverse direction of a first direction DR1 and a second direction DR2. In addition, in a region of the unit pixel PXU12, the first emission layer EML12a is disposed on the lower right, the second emission layer EML12b is disposed in the middle, and the third emission layer EML12c is disposed on the upper left.

Emission layers EML21a, EML21b, and EML21c of the unit pixel PXU21 are arranged in a diagonal direction between the reverse direction of the first direction DR1 and the second direction DR2. In addition, in a region of the unit pixel PXU21, the first emission layer EML21a is disposed on the upper left, the second emission layer EML21b is disposed in the middle, and the third emission layer EML21c is disposed on the lower right.

Emission layers EML22a, EML22b, and EML22c of the unit pixel PXU22 are arranged in a diagonal direction between the reverse direction of the first direction DR1 and the reverse direction of the second direction DR2. In addition, in a region of the unit pixel PXU22, the first emission layer EML22a is disposed on the lower left, the second emission layer EML22b is disposed in the middle, and the third emission layer EML22c is disposed on the upper right.

In this case, a laser drilling position LDP and a connecting electrode CE at which laser drilling can be performed may be disposed at a center of the arrangement of the light emitting elements arranged in a rhombus shape. The embodiment of FIG. 8 has a merit of securing a relatively wide laser drilling position LDP even though a space where one unit pixel PXU is to be formed is reduced in a high resolution light emitting display device.

The embodiment of FIG. 8 is an embodiment of re-disposing in a rhombus arrangement based on the planar shape and arrangement of each emission layer (or opening of the pixel definition film 380 (refer to FIG. 3)) according to the embodiment of FIG. 2, depending on embodiments, the embodiment of FIG. 6 may be re-disposed in a rhombus arrangement, or the emission layer (or the opening of the pixel definition film 380 (refer to FIG. 3)) having other structures can be arranged in a rhombus shape.

On the other hand, depending on embodiments, a direction of the light emitting element dispositions SDLs disposed in a chevron shape CS may be different from the embodiment of FIG. 2 and the embodiment of FIG. 6, and thus will be described hereinafter.

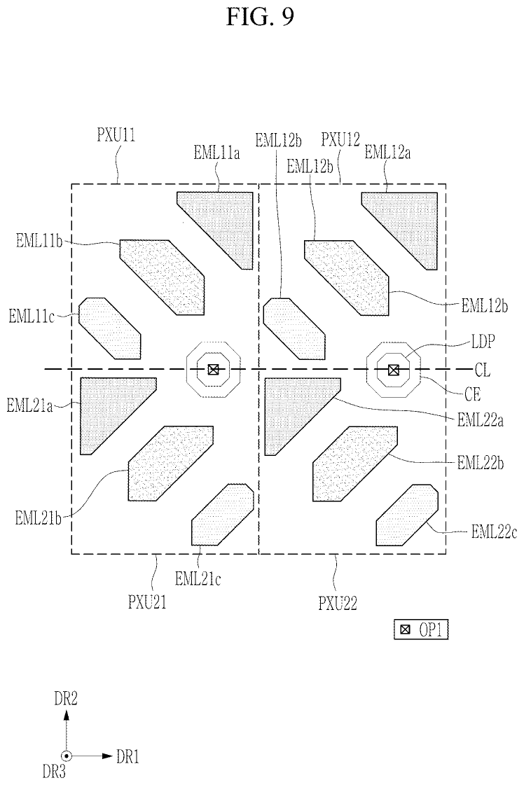

FIG. 9 is a variant embodiment of the embodiment of FIG. 2.

First, the disposition of each emission layer in FIG. 9 will be described in detail.

Emission layers EML11a, EML11b, and EML11c of the unit pixel PXU11 are arranged in a diagonal direction between the first direction DR1 and the second direction DR2. In addition, in a region of the unit pixel PXU11, the first emission layer EML11a is disposed on the upper right, the second emission layer EML11b is disposed in the middle, and the third emission layer EML11c is disposed on the lower left.

On the other hand, emission layers EML21a, EML21b, and EML21c of the unit pixel PXU21 area arranged in a diagonal direction between the reverse direction of the first direction DR1 and the second direction DR2. In addition, in a region of the unit pixel PXU21, the first emission layer EML21a is disposed on the upper left, the second emission layer EML21b is disposed in the middle, and the third emission layer EML21c is disposed on the lower right.

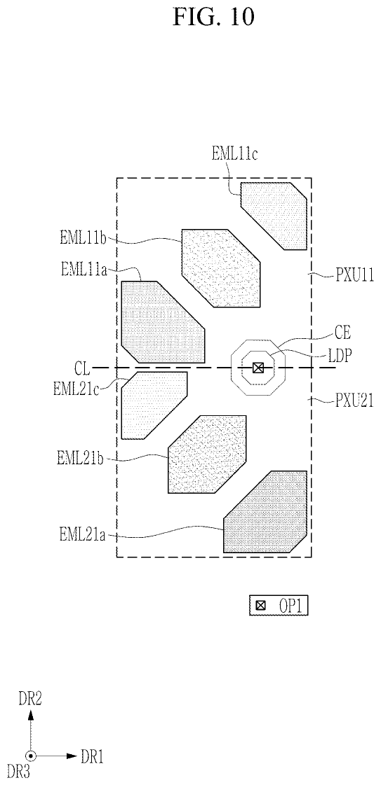

Meanwhile, the disposition of each emission layer in FIG. 10 will be described in detail.

Emission layers EML11a, EML11b, and EML11c of the unit pixel PXU11 are arranged in a diagonal direction between the reverse direction of the first direction DR1 and the reverse direction of the second direction DR2. In addition, in a region of the unit pixel PXU11, the first emission layer EML11a is disposed on the lower left, the second emission layer EML11b is disposed in the middle, and the third emission layer EML11c is disposed on the upper right.

On the other hand, emission layers EML21a, EML21b, and EML21c of the unit pixel PXU21 area arranged in a diagonal direction between the first direction DR1 and the reverse direction of the second direction DR2. In addition, in a region of the unit pixel PXU21, the first emission layer EML21a is disposed on the lower right, the second emission layer EML21b is disposed in the middle, and the third emission layer EML21c is disposed on the upper left.

In the above embodiments, an embodiment in which emission layers closest to each other between adjacent unit pixel PXUs have different colors is illustrated.

Hereinafter, a comparative example in which emission layers of the same color are disposed to be adjacent to each other, unlike the above-described embodiment, will be described.

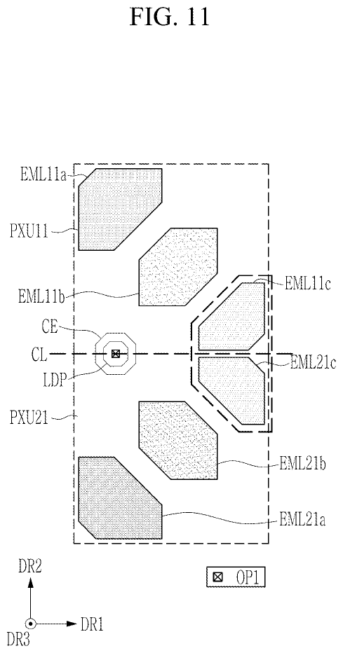

FIG. 11 is a top plan view of a light emitting element and a laser drilling position according to a comparative example.

In a comparative example, emission layers EML11a, EML11b, and EML11c of a unit pixel PXU11 are arranged in a diagonal direction between the reverse direction of a first direction DR1 and a second direction DR2. In addition, in a region of the unit pixel PXU11, the first emission layer EML11a is disposed on the upper left, the second emission layer EML11b is disposed in the middle, and the third emission layer EML11c is disposed on the lower right.

On the other hand, emission layers EML21a, EML21b, and EML21c of the unit pixel PXU21 are arranged in a diagonal direction between the reverse direction of the first direction DR1 and the reverse direction of the second direction DR2. In addition, in a region of the unit pixel PXU21, the first emission layer EML21a is disposed on the lower left, the second emission layer EML21b is disposed in the middle, and the third emission layer EML21c is disposed on the upper right.

As a result, in a comparative example of FIG. 11, third emission layers EML11c and EML21c of the same color are disposed adjacent to each other between two adjacent unit pixel PXUs, such as the part bounded by the dotted line.

Such a comparative example of FIG. 11 has the following drawbacks compared to another embodiment.

The comparative example of FIG. 11 is a light emitting display device for displaying high resolution, but since third emission layers EML11c and EML21c of the same color are disposed adjacent to each other, there is a problem in that a user may recognize the two third emission layers EML11c and EML21c connected by dotted lines as one emission layer or light emitting element such that the user may recognize an image with relatively low resolution.

In addition, in the comparative example of FIG. 11, all first emission layers EML11a and EML21a are disposed to the right of the unit pixels PXU11 and PXU21, and all third emission layers EML11c and EML21c are disposed to the left of the unit pixels PXU11 and PXU21. Accordingly, for color jamming of FIG. 7 with respect to the comparative example of FIG. 11, colors corresponding to the first emission layers EML11a and EML21a may appear on the right side, and colors corresponding to the third emission layers EML11c and EML21c may appear on the left side. As a result, there may be a drawback that greatly causes color jamming.

Therefore, unlike the comparative example, in the present embodiment, it is confirmed that different colors of emission layers closest to each other between unit pixels PXU are disposed to eliminate the problem of deteriorated resolution and improve the display quality by reducing the color jamming phenomenon.

Although embodiments of the present inventive concepts have been described, various modifications and similar arrangements of such embodiments will be apparent to a person of ordinary skill in the art. Accordingly, the inventive concepts are not limited to such embodiments, but rather to the scope and spirit of the appended claims.

What is claimed is:

1. A light emitting display device comprising:
a substrate including a surface defined by a first direction and a second direction, and a thickness defined by a third direction;
a first unit pixel disposed on the substrate and including a first light emitting region, a second light emitting region, and a third light emitting region configured to emit first color light, second color light, and third color light, respectively; and
a second unit pixel disposed on the substrate and including the first light emitting region, the second light emitting region, and the third light emitting region configured to emit the first color light, the second color light, and the third color light, respectively;
wherein the first unit pixel and the second unit pixel are adjacently arranged in the second direction,
the first light emitting region, the second light emitting region, and the third light emitting region of the first unit pixel are sequentially arranged in a first diagonal direction with respect to the first and second directions,
the first light emitting region, the second light emitting region, and the third light emitting region of the second unit pixel are sequentially arranged in a second diagonal direction with respect to the first and second directions,
the first diagonal direction is different from the second diagonal direction, and
a laser drilling position opening formed by laser drilling is located on a center line between the first unit pixel and the second unit pixel, and does not overlap the first, second, and third light emitting regions of the first unit pixel and the second unit pixel.

2. The light emitting display device of claim 1, wherein
the first and second diagonal directions are arranged in a chevron shape,
the chevron shape includes a center point where the first and second diagonal directions meet, a first end located along the first diagonal distal from the center point, and a second end located along the second diagonal direction distal from the center point,
the first light emitting regions of the first and second unit pixels are disposed near the first end of the chevron shape and near the center point of the chevron shape, respectively, and
the third light emitting regions of the first and second unit pixels are disposed near the center point of the chevron shape and near the second end of the chevron shape, respectively.

3. The light emitting display device of claim 1, wherein
the third light emitting region of the first unit pixel and the first light emitting region of the second unit pixel are disposed near the center point of the chevron shape.

4. The light emitting display device of claim 1, further comprising a third unit pixel and a fourth unit pixel,
wherein the first unit pixel, the second unit pixel, the third unit pixel, and the fourth unit pixel are arranged in a 2×2 matrix format,
each of the third and fourth unit pixels include the first, second, and third light emitting regions,
the first light emitting region, the second light emitting region, and the third light emitting region of the third unit pixel are sequentially arranged in a third diagonal direction, and
the first light emitting region, the second light emitting region, and the third light emitting region of the fourth unit pixel are sequentially arranged in a fourth diagonal direction.

5. The light emitting display device of claim 4, wherein
the first diagonal direction and the third diagonal direction are a same direction, and
the second diagonal direction and the fourth diagonal direction are the same direction.

6. The light emitting display device of claim 4, wherein
the first diagonal direction and the fourth diagonal direction are parallel but in opposite directions, and
the second diagonal direction and the third diagonal direction are parallel but in the opposite directions.

7. The light emitting display device of claim 1 wherein
each of the first light emitting region, the second light emitting region, and the third light emitting region have a planar polygonal shape.

8. The light emitting display device of claim 7, wherein
the planar polygonal shape of each of the first light emitting region, the second light emitting region, and the third light emitting region have at least one chamfered edge.

9. The light emitting display device of claim 1, further comprising:
a semiconductor layer that is disposed on the substrate;
a gate electrode that is disposed on the semiconductor layer;
an interlayer insulating layer that covers the gate electrode;
an anode that is disposed on the interlayer insulating layer;
a pixel definition film that includes a first opening overlapping the anode;
an emission layer that is disposed on the anode; and
a cathode that is disposed on the pixel definition film and the emission layer wherein each of the first light emitting region, the second light emitting region, and the third light emitting region include the first opening of the pixel definition film.

10. The light emitting display device of claim 9, wherein
each of the first, second, and third light emitting regions includes a light emitting element that comprises the anode, the emission layer, and the cathode.

11. The light emitting display device of claim 10, wherein
the anode is connected to the semiconductor layer through a second opening disposed in the interlayer insulating layer.

12. The light emitting display device of claim 9, wherein
a connecting electrode is disposed on the interlayer insulating layer at the laser drilling position opening formed by the laser drilling.

13. The light emitting display device of claim 12, wherein
the connecting electrode is disposed in the laser drilling position opening, and
the connecting electrode is connected to the cathode in the laser drilling position opening.

14. The light emitting display device of claim 13, wherein
the connecting electrode is disposed on a same layer as the anode,
the connecting electrode extends to an auxiliary low voltage line, and
a material of the connecting electrode is a same material as the anode.

15. The light emitting display device of claim 13, further comprising:
a driving low voltage line disposed on the substrate; and
an auxiliary driving low voltage line disposed on the substrate,
wherein the driving low voltage line and the auxiliary low voltage line are disposed on different layers,
the driving low voltage line and the auxiliary low voltage line extend in different directions,
the driving low voltage line and the auxiliary driving low voltage line are configured to transmit a driving low voltage to the cathode.

16. The light emitting display device of claim 15, wherein
the connecting electrode connects the cathode to the auxiliary driving low voltage line.

17. The light emitting display device of claim 1, wherein
the first unit pixel comprises a first pixel, a second pixel, and a third pixel which include the first, second, and third light emitting regions that emit the first, second, and third color light, respectively,
the first pixel comprises a first pixel driver and a first light emitting element,
the second pixel comprises a second pixel driver and a second light emitting, and
the third pixel comprises a third pixel driver and a third light emitting element.

18. The light emitting display device of claim 17, wherein
each of the first pixel driver, the second pixel driver, and the third pixel driving driver comprises a driving transistor and a storage capacitor,
the storage capacitor is connected to a gate electrode of the driving transistor,
an electrode of the driving transistor included in the first pixel driver is connected to an anode of the first light emitting element,
an electrode of the driving transistor included in the second pixel driver is connected to an anode of the second light emitting element, and
an electrode of the driving transistor included in the third pixel driver is connected to an anode of the third light emitting element.

19. The light emitting display device of claim 18, wherein
each of the first pixel driver, the second pixel driver, and the third pixel driver further includes an input transistor, and
the input transistor transmits a data voltage from a data line to the gate electrode of the driving transistor.

20. The light emitting display device of claim 19, wherein
each of the first pixel driver, the second pixel driver, and the third pixel driver further includes an initialization transistor,
a voltage of each of the anode of the first light emitting element, the anode of the second light emitting element, and the anode of the third light emitting element is sensed or initialized by the initialization transistor of the first, second, and third pixel drivers, respectively.
